(19) United States
(12) Patent Application Publication
(10) Pub. No.: US 2026/0238242 A1
(43) Pub. Date: Aug. 13, 2026

(54) PRACTICAL MACHINE LEARNING BASED DPD FOR WIDEBAND MULTIBAND RADIOS

(71) Applicant: Telefonaktiebolaget LM Ericsson (publ), Stockholm (SE)

(72) Inventor: S M Shahrear TANZIL, Ottawa (CA)

(73) Assignee: Telefonaktiebolaget LM Ericsson (publ), Stockholm (SE)

(21) Appl. No.: 19/160,036

(22) PCT Filed: Mar. 3, 2023
(86) PCT No.: PCT/IB2023/052004

§ 371 Date: Aug. 27, 2025

(51) Int. Cl. H04B 1/04; H04B 1/00

(52) U.S. Cl. CPC H04B 1/0475; H04B 1/0067; H04B 2001/0425

(57) ABSTRACT

Systems and methods for Machine Learning (ML) based Digital Predistortion (DPD) for a radio node are disclosed. In one embodiment, a radio node for a wireless network includes a ML based DPD system configured to digitally predistort one or more input signals to provide a DPD output. The ML based DPD system includes, for each input signal of the one or more input signals, separate ML models configured to generate respective ML model outputs based on respective input feature sets comprising respective vectors of absolute values of filtered versions of an input vector comprising a plurality of complex samples of the input signal. The radio node further includes transmit circuitry configured to process the DPD output to provide a predistorted radio signal and power amplifier circuitry configured to amplify the predistorted radio signal.

### TECHNICAL FIELD

The present disclosure relates to digital predistortion (DPD) in a transmitter of a radio node such as, e.g., a base station of a radio access network of a cellular communications system.

### BACKGROUND

In a 3^{rd} Generation Partnership Project (3GPP) Radio Access Network (RAN), non-linear behavior of a Power Amplifier (PA) in a base station (e.g., a gNodeB (gNB) in the case of New Radio (NR) or evolved NodeB (eNB) in the case of Long Term Evolution (LTE)) causes out-of-band distortion. This out-of-band distortion may result in violation of 3GPP Adjacent Channel Leakage Ratio (ACLR) requirements. One option to address this issue is to operate the PA at lower power such that the PA behavior is linear. However, this option makes the PA inefficient and leads to higher energy consumption in the network. Another option is to predistort input signals in the digital domain to compensate for the non-linear behavior of the PA. In other words, together the predistortion and the non-linear behavior of the PA behave as a linear entity. This approach is known as Digital Predistortion (DPD) and widely used in the industry.

One of the key challenges when using DPD is energy consumption in the radio. As a result, complexity reduction in the DPD is always an active area of research. Modern radio designs include more frequency bands within the same PA to increase capacity while keeping energy consumption low; however, such radio designs require a DPD system that is difficult to implement. In addition, a modular and scalable DPD solution is desired so that the same design can be adapted to cover different scenarios to reduce development cost.

### SUMMARY

Systems and methods for Machine Learning (ML) based Digital Predistortion (DPD) for a radio node are disclosed. In one embodiment, a radio node for a wireless network comprises a ML based DPD system configured to digitally predistort one or more input signals to provide a DPD output. The ML based DPD system comprises, for each input signal of the one or more input signals, separate ML models configured to generate respective ML model outputs based on respective input feature sets comprising respective vectors of absolute values of filtered versions of an input vector comprising a plurality of complex samples of the input signal. The radio node further comprises transmit circuitry configured to process the DPD output to provide a predistorted radio signal and power amplifier circuitry configured to amplify the predistorted radio signal. In this manner, a ML based DPD system for a radio node is provided that can use shallow ML models (e.g., few layers of neural network, few tress in random forest, or the like), thereby reducing complexity and cost while maintaining a desired level of performance.

In one embodiment, the one or more input signals consist of an input signal, and the ML based DPD system comprises, for each m-th delay branch of one or more delay branches of the ML based DPD system: a first delay configured to apply a first delay for the m-th delay branch to an input vector comprising a plurality of complex samples of an input signal to provide a first delayed input vector for the m-th delay branch, a first filter configured to filter the first delayed input vector for the m-th delay branch to provide a first filtered and delayed input vector for the m-th delay branch, a second delay configured to apply a second delay for the m-th delay branch to the input vector to provide a second delayed input vector for the m-th delay branch, a second filter for the m-th delay branch configured to filter the second delayed input vector for the m-th delay branch to provide a second filtered and delayed input vector for the m-th delay branch, an absolute value function configured to provide a vector of absolute values for the m-th delay branch comprising an absolute value of each complex value in the second filtered and delayed input vector for the m-th delay branch, an ML model configured to receive the vector of absolute values for the m-th delay branch as an input feature and output an ML model output vector for the m-th delay branch, and a multiplication function for the m-th delay branch configured to multiply the first filtered and delayed input vector for the m-th delay branch and the ML model output vector for the m-th delay branch to provide a component of a DPD output for the m-th delay branch. The ML based DPD system further comprises a combining function configured to combine the components of the DPD output for the one or more delay branches to provide the DPD output.

In one embodiment, the combining function is an addition function. In another embodiment, the combining function is an ML model.

In one embodiment, for each m-th delay branch, the first delay and the second delay are such that the first filtered and delayed input vector for the m-th delay branch and the ML model output vector for the m-th delay branch are time-aligned at the multiplication function for the m-th delay branch.

In one embodiment, the one or more delay branches comprise two or more delay branches.

In one embodiment, the input signal is a single band input signal. In another embodiment, the input signal is a multi-band input signal.

In another embodiment, the one or more input signals comprise two or more input signals for two or more frequency bands, respectively. In one embodiment, the ML based DPD system comprises two or more ML based DPD subsystems for the two or more frequency bands, respectively. In one embodiment, for b=1, . . . , B where B is the number of frequency bands in the two or more frequency bands, each b-th ML based DPD subsystem from among the two or more ML based DPD subsystems comprises, for each m-th delay branch of one or more delay branches of the b-th ML based DPD subsystem, a first delay configured to apply a first delay for the m-th delay branch to a b-th input vector comprising a plurality of complex samples of the b-th input signal to provide a first delayed input vector for the m-th delay branch, a first filter configured to filter the first delayed input vector for the m-th delay branch to provide a first filtered and delayed input vector for the m-th delay branch. The b-th ML based DPD system further comprises, for each m-th delay branch, for each b-th frequency band, a b-th delay for the m-th delay branch configured to apply a b-th delay for the m-th delay branch to the b-th input vector to provide a b-th delayed input vector for the m-th delay branch, a b-th filter for the m-th delay branch configured to filter the b-th delayed input vector for the m-th delay branch to provide a b-th filtered and delayed input vector for the m-th delay branch, and an absolute value function configured to provide a b-th vector of absolute values for the m-th delay branch comprising an absolute value of each complex value in the b-th filtered and delayed input vector for the m-th delay branch. The b-th ML based DPD system further comprises, for each m-th delay branch, an ML model configured to receive the B vectors of absolute values for the m-th delay branch as input features and output an ML model output vector for the m-th delay branch and a multiplication function for the m-th delay branch configured to multiply the first filtered and delayed input vector for the m-th delay branch and the ML model output vector for the m-th delay branch to provide a component of a DPD output for the m-th delay branch. The b-th ML based DPD system further comprises a combining function configured to combine the components of the DPD output for the one or more delay branches to provide a DPD output for the b-th frequency band.

In one embodiment, the combining function is an addition function. In another embodiment, the combining function is an ML model.

In one embodiment, the ML based DPD system further comprises combining circuitry configured to combine the DPD outputs for the B frequency bands to provide the DPD output of the ML based digital DPD system.

Corresponding embodiments of a method performed by a radio node for a wireless network are also disclosed. In one embodiment, the method comprises digitally predistorting one or more input signals via a ML based DPD system to provide a DPD output. The ML based DPD system comprises, for each input signal of the one or more input signals, separate ML models configured to generate respective ML model outputs based on respective input feature sets comprising respective vectors of absolute values of filtered versions of an input vector comprising a plurality of complex samples of the input signal. The method further comprises processing the DPD output to provide a predistorted radio signal and amplifying the predistorted radio signal.

### BRIEF DESCRIPTION OF THE DRAWINGS

The accompanying drawing figures incorporated in and forming a part of this specification illustrate several aspects of the disclosure, and together with the description serve to explain the principles of the disclosure.

FIG. 1 illustrates a radio node including a Machine Learning (ML)-based Digital Predistortion (DPD) system receiving a single input signal in accordance with one embodiment of the present disclosure;

FIG. 2 shows an existing ML-based DPD system;

FIG. 3 illustrates the ML-based DPD system of FIG. 1 for the single input signal use case, in accordance with one embodiment of the present disclosure;

FIG. 4 is a flow chart that illustrates the operation of the radio node of FIG. 1 in accordance with one embodiment of the present disclosure;

FIG. 5 is a flow chart that illustrates step 400 of FIG. 4 in more detail, in accordance with one embodiment of the present disclosure;

FIG. 6 illustrates an example embodiment of a radio node including a ML based DPD system for the multi-input or multi-band case;

FIGS. 7 and 8 illustrate an example embodiment of the ML-based multi-band DPD system of FIG. 6;

FIG. 9 is a flow chart that illustrates the operation of the radio node of FIG. 6 in accordance with one embodiment of the present disclosure; and

FIG. 10 is a flow chart that illustrates step 900 in more detail, in accordance with one embodiment of the present disclosure.

### DETAILED DESCRIPTION

The embodiments set forth below represent information to enable those skilled in the art to practice the embodiments and illustrate the best mode of practicing the embodiments.

Upon reading the following description in light of the accompanying drawing figures, those skilled in the art will understand the concepts of the disclosure and will recognize applications of these concepts not particularly addressed herein. It should be understood that these concepts and applications fall within the scope of the disclosure.

Radio Node: As used herein, a “radio node” is either a radio access node or a wireless communication device.

Radio Access Node: As used herein, a “radio access node” or “radio network node” or “radio access network node” is any node in a Radio Access Network (RAN) of a cellular communications network that operates to wirelessly transmit and/or receive signals. Some examples of a radio access node include, but are not limited to, a base station (e.g., a New Radio (NR) base station (gNB) in a Third Generation Partnership Project (3GPP) Fifth Generation (5G) NR network or an enhanced or evolved Node B (eNB) in a 3GPP Long Term Evolution (LTE) network), a high-power or macro base station, a low-power base station (e.g., a micro base station, a pico base station, a home eNB, or the like), a relay node, a network node that implements part of the functionality of a base station or a network node that implements a gNB Distributed Unit (gNB-DU)) or a network node that implements part of the functionality of some other type of radio access node.

Communication Device: As used herein, a “communication device” is any type of device that has access to an access network. Some examples of a communication device include, but are not limited to: mobile phone, smart phone, sensor device, meter, vehicle, household appliance, medical appliance, media player, camera, or any type of consumer electronic, for instance, but not limited to, a television, radio, lighting arrangement, tablet computer, laptop, or Personal Computer (PC). The communication device may be a portable, hand-held, computer-comprised, or vehicle-mounted mobile device, enabled to communicate voice and/or data via a wireless or wireline connection.

Wireless Communication Device: One type of communication device is a wireless communication device, which may be any type of wireless device that has access to (i.e., is served by) a wireless network (e.g., a cellular network). Some examples of a wireless communication device include, but are not limited to: a User Equipment device (UE) in a 3GPP network, a Machine Type Communication (MTC) device, and an Internet of Things (IoT) device. Such wireless communication devices may be, or may be integrated into, a mobile phone, smart phone, sensor device, meter, vehicle, household appliance, medical appliance, media player, camera, or any type of consumer electronic, for instance, but not limited to, a television, radio, lighting arrangement, tablet computer, laptop, or PC. The wireless communication device may be a portable, hand-held, computer-comprised, or vehicle-mounted mobile device, enabled to communicate voice and/or data via a wireless connection.

Note that the description given herein focuses on a 3GPP cellular communications system and, as such, 3GPP terminology or terminology similar to 3GPP terminology is oftentimes used. However, the concepts disclosed herein are not limited to a 3GPP system.

Existing solutions for Digital Predistortion (DPD) have certain challenges. To reduce computational cost in the radio node, a Look-Up Table (LUT) based DPD solution is oftentimes used. In the LUT used for DPD, inputs are segmented into different grid points according to amplitude or power level. The goal of LUT is to store DPD outputs for different input amplitude levels. As a result, LUT based DPD can provide very fast DPD with low computational cost.

However, as more frequency bands are added in the same PA via a multi-band input signal, frequency selective DPD is required to achieve desirable performance while keeping the computational cost low. In frequency selective DPD, each frequency band of the input signal is treated as a separate input. For example, for a triple band use case, the LUT needs to store values in a three-dimensional grid point. When running in the forward path, this approach needs dedicated three-dimensional interpolation to achieve desirable performance. If it is desired for the same DPD to be reused (e.g., the same Application Specific Integrated Circuit (ASIC) on which the DPD system is implemented to be reused) for dual band, then a dedicated two-dimensional interpolation function is also needed. So, different functionalities are needed in the same DPD system (e.g., in the same ASIC) to cover different multi-band scenarios. In addition, total number of grid points are growing exponentially with the number of frequency bands. This leads to higher cost in parameter identifications.

There have been a few attempts to use Machine Learning (ML) to make scalable and modular solution, see, e.g., Patent Cooperation Treaty (PCT) Patent Application Publication Number WO 2022/177482 A1 entitled “Method and device(s) for supporting machine learning based crest factor reduction and digital predistortion”; Y. Wu, U. Gustavsson, A. G. i. Amat and H. Wymeersch, “Residual Neural Networks for Digital Predistortion,” GLOBECOM 2020-2020 IEEE Global Communications Conference, Taipei, Taiwan, 2020, pp. 01-06, doi: 10.1109/GLOBECOM42002.2020.9322327; and Y. Wu, U. Gustavsson, A. G. i. Amat and H. Wymeersch, “Residual Neural Networks for Digital Predistortion,” GLOBECOM 2020-2020 IEEE Global Communications Conference, Taipei, Taiwan, 2020, pp. 01-06, doi: 10.1109/GLOBECOM42002.2020.9322327. In most of the solutions, a delayed version of the input signal and its properties such as real part, imaginary part, and envelope are considered as input features for the ML network. This approach works for lower bandwidth signals. However, when there are higher bandwidth signals or multicarrier signals, several delayed versions of the input signal need to be considered. As a result, the ML network grows quickly, and number of parameters becomes higher and sometimes even more than when using a LUT based DPD solution.

Systems and methods are disclosed herein that address the aforementioned and/or other challenges with existing DPD solutions. In one embodiment, a ML-based DPD system is provided, where input features of ML models (also referred to herein as “ML networks”) are generated based on a filtered version(s) of the input signal(s). As a result, the ML model needs fewer parameters while providing improved performance. Embodiments of the present disclosure include one or more of the following aspects:
The previous attempts to use ML to provide a DPD solution noted above use delayed versions of the input signal to enhance memory depth and, as such, the resulting ML network size grows quickly. In embodiments of the present disclosure, filters are used to enhance memory depth of the DPD. As a result of the filtering, a shallow ML network can be used while achieving desirable performance. Note that, as used herein, a “shallow ML network” or “shallow ML model” is a ML network/model having up to a certain maximum number (e.g., one, two, or three) ML layers (e.g., up to three layers in a neural network implementation of a ML network or up to up to three layers/levels in a deep learning based ML network).
The previous attempts to use ML to provide a DPD solution noted above target capturing the whole nonlinearity required in the DPD using ML. However, phase information of the signal is very sensitive. In some embodiments of the ML-based DPD system disclosed herein, phase information is used separately and does not pass-through the ML network. As a result, only the amplitude or absolute value of complex samples are needed in the ML network, whereas the existing DPS solutions that use ML all require real and imaginary part of the signals to pass through the ML network. This step reduces number of input features required in the ML network, which leads to fewer parameters in the ML network. This step also improves performance.
In some embodiments, filtering of the input signal(s) is used together with a ML network in several parallel branches. This step keeps the ML networks in the separate branches very small and provides for parallel implementation.

Embodiments of the ML-based DPD system disclosed herein may provide a number of advantages over existing DPD systems. For example, these advantages may include any one or more of the following:
In some embodiments, the ML-based DPD system is a multi-band DPD system that input signals for the different frequency bands and provides a multi-band DPD output without using a multi-dimensional LUT. As a result, the same base design can be reused for different band combinations.
By using filtering, the ML-based DPD system can use shallow ML networks to achieve desirable performance while keeping computational cost low. This filtering of the input signal(s) enables support of higher bandwidths and multi-band/multi-carrier scenarios.
The ML-based DPD system described herein can use any type of ML network.
In some embodiments, the ML-based DPD system disclosed herein enables low-cost development and verification.
In some embodiments, since the ML network(s) use a small number of parameters, dynamic adaptation of the ML network(s) can be used.

More detailed embodiments of the present disclosure will now be described. First, embodiments of a ML-based DPD system are described for single input use case. The single input use case can be considered as a single band use case or multiband use case where all the frequency bands are combined before DPD. In both cases, the proposed ML-based DPD system can be implemented.

Let us use x(n) to denote n-th input complex signal, and x(n−m) represents m-th delayed samples. X=[x(n) x(n−1) . . . . x(n−m +1) x(n−m)] is used to represent input vector of complex samples. Please note that x(n) is a complex signal, and thus it contains real and imaginary parts. For the multi-band scenario for a single (multi-band) input signal use case, it is assumed that all the bands are combined at a higher sampling rate according to their relative distances from a reference frequency in the frequency domain. Let us use x₁(n), x₂(n), . . . , x_{B} (n) to denote input complex samples from B frequency bands. In this case, x(n)=x₁(n)e^{-iω}^{₁}^{t}+x₂(n)e^{-iω}^{₂}^{t}+. . . +x_{B}(n)e^{-iω}^{_{B}}^{t}, and X represents the same as the input vector.

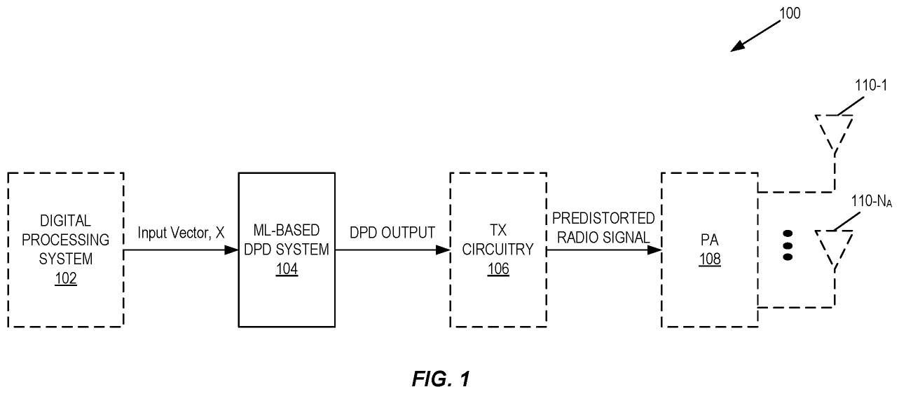

In this regard, FIG. 1 illustrates a radio node 100 including a ML-based DPD system 104 receiving a single input signal in accordance with one embodiment of the present disclosure. Optional blocks are represented by dashed boxes/lines. As illustrated, a digital processing system 102 (e.g., a Digital Signal Processor (DSP) or the like) generates an input vector (X) including complex samples of an input signal and provides the input vector (X) to the ML-based DPD system 104. The ML-based DPD system 104 may be implemented in hardware, software, or a combination thereof. In one example embodiment, the ML-based DPD system 104 is implemented by one or more ASICs. While the details of the ML-based DPD system 104 are described below, at a high-level, the ML-based DPD system 104 processes the input vector (X) to provide a DPD output, which includes complex samples that represent a predistorted version of the input signal. Transmit circuitry 106 processes the DPD output to provide a predistorted radio (e.g., radio frequency) signal, which is amplified by a power amplifier (PA) 108 and transmitted via one or more antennas 110-1 through 110-N_{A}, where N_{A} is the number of antennas. As will be appreciated by those of ordinary skill in the art, the transmit circuitry 106 includes digital to analog conversion circuitry, upconversion circuitry (e.g., mixers), filters, and/or the like.

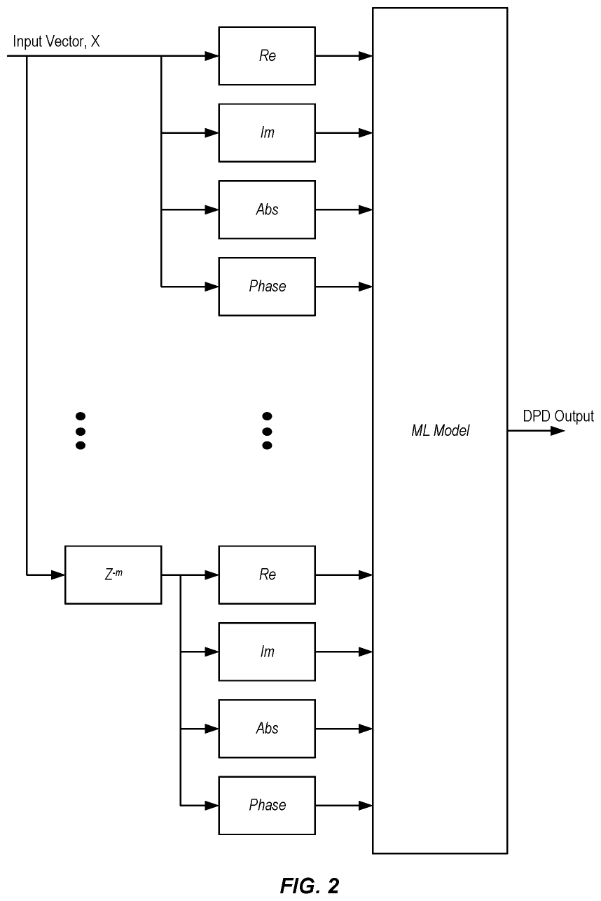

Before describing details of the ML-based DPD system 104, a brief description of the existing ML-based DPD system is beneficial. In this regard, FIG. 2 shows the existing ML-based DPD system. In this case, properties of a complex input signal such as real part, imaginary part, absolute value, and phase information are sent to the ML model. To enhance memory depth, the ML model also takes m previous samples into account. One can use any ML model such as neural network, tree-based ML model, recurrent neural network, convolutional neural network, or any one of their different variants. However, as can be seen in FIG. 2, the number of input features that are input to the ML model grows quickly as the number of memory terms increases, which is required for the multi-band (i.e., multi-carrier) input scenario or wider bandwidth scenarios.

Returning to the description of the ML-based DPD system 104, to tackle memory terms, the ML-based DPD system 104 filters the input vector (X), or multiple delayed versions thereof, before processing by a ML model(s). In one embodiment, the filtering is performed via a filter(s) having complex filtering weights, or coefficients, and optionally having variable size. In one embodiment, the filter(s) are predetermined and fixed. In another embodiment, the filter(s) are trained together with the ML model(s) used by the ML-based DPD system 104. In addition, as described below in detail, phase information of the (filtered) input signal bypasses the ML model(s) and is preserved by multiplying the filtered input signal together with the ML model output(s). This step removes the need to provide the real part, imaginary part, and phase information of the input signal to the ML model(s) as input features.

In some embodiments, to enhance the memory depth, the ML-based DPD system 104 includes parallel delay branches where each delay branch takes care a part of different memory depth and nonlinearity of the PA 108. As a result, the ML models used by the ML-based DPD system 104 can be very thin, or shallow, as compared to that needed for the existing ML-based DPD solution.

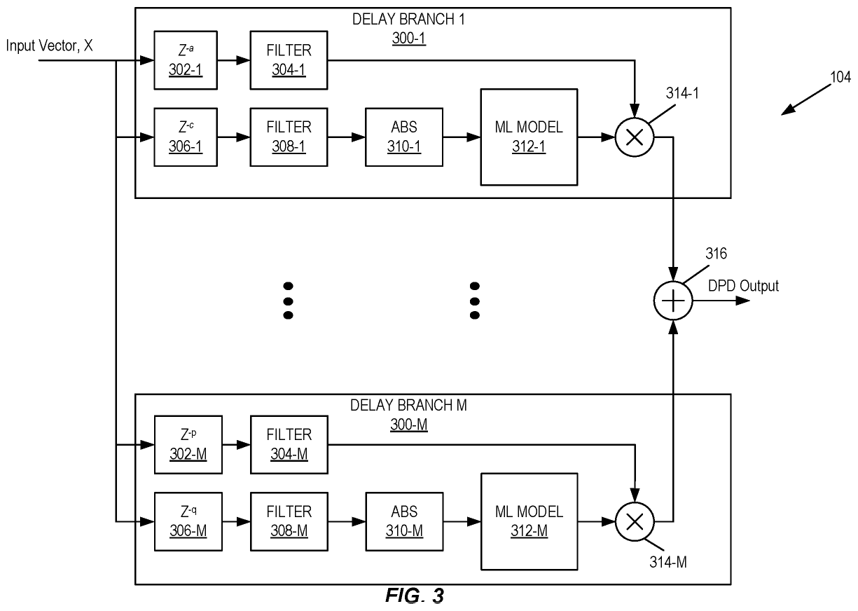

FIG. 3 illustrates the ML-based DPD system 104 for the single input signal use case, in accordance with one embodiment of the present disclosure. As illustrated, the ML-based DPD system 104 includes multiple delay branches 300-1 to 300-M. For each delay branch 300-m where m=1, . . . , M, the ML-based DPD system 104 includes a first delay 302-m that applies a delay (e.g., Z^{-a} in the case of the first delay branch 300-1) to the input vector (X) and a first filter 304-m that filters the delayed input vector output by the first delay 302-m to provide a first delayed and filtered input vector for the delay branch 300-m. The delay branch 300-m also includes a second delay 306-m that applies a delay (e.g., Z^{-c} in the case of the first delay branch 300-1) to the input vector (X) and a second filter 308-m that filters the delayed input vector output by the second delay 306-m to provide a second delayed and filtered input vector. The delay branch 300-m also includes an absolute value function 310-m that receives the second delayed and filtered input vector and outputs a vector including an absolute value of the corresponding complex sample of the second delayed and filtered input vector. The vector of absolute values is provided as an input feature to a ML model 312-m. The ML model 312-m provides a ML model output responsive to the vector of absolute values. In one embodiment, the ML model 312-m is a shallow ML model (e.g., includes three or less layers, more preferably two or less layers, or even more preferably a single layer). In one example embodiment, the ML model 312-m is a neural network including five neurons per branch where “relu” is used as an activation function. The delay branch 300-m further includes a multiplier 314-m that multiples the first delayed and filtered input vector output by the first filter 304-m and the ML model output to provide a component of the DPD output for the delay branch 300-m. A combiner 316 combines the M components of the DPD output from the M delay branches 300-1 to 300-M to provide the DPD output. Note that, in the illustrated example embodiments, the combiner 316 is an adder. However, other combining mechanisms can be used. For example, in another embodiment, the combiner 316 is another ML model that combines the M components of the DPD output from the M delay branches 300-1 to 300-M. This ML model will take care of the interaction among different delay branches and is, in one example embodiment, trained together with the other ML models 312-1 to 312-M to provide the desired DPD output for a given input vector.

Note that, in one embodiment, delays applied by the first delay 302-m and the second delay 306-m provide the desired memory depth for the delay branch 300-m and, in one embodiment, the delay applied by the second delay 306-m further includes an additional delay such that the first delayed and filtered input vector and the ML model output are time-aligned at the inputs of the multiplier 314-m. The different delay branches 300-1 to 300-M provide different memory delays. In one embodiment, the memory terms in the different delay branches 300-1 to 300-M are set by changing the amount of delay applied by the delays 302-m and 306-m.

Also note that the filters 304-m and 308-m take complex input signals and filter those complex input signals in accordance with respective sets of complex filter coefficients. In one embodiment, these complex filter coefficients are predetermined and fixed. In another embodiment, these complex filter coefficients are trained (and updated if desired) together with the ML model 312-m. In one embodiment, the filters 304-m and 308-m operate at a lower sampling rate as compared to the ML model 312-m where the outputs of the filters 304-m and 308-m are up-sampled according to the desired sampling rate of the ML model 312-m.

In one embodiment, the filters 304-m and 308-m apply a filtering function to multiple complex samples of their respective input signals to provide a filtered, complex samples. Further, the filtering may be such that the output sampling rate of the filters 304-m and 308-m is less than the sampling rate of the respective input signals. This may further reduce the complexity of the ML model 312-m.

Importantly, the ML model 312 only takes into account the absolute values of the delayed and filtered input vector. As a result, the ML model 312-m can be significantly more shallow than the ML model required using the existing ML-based DPD solutions.

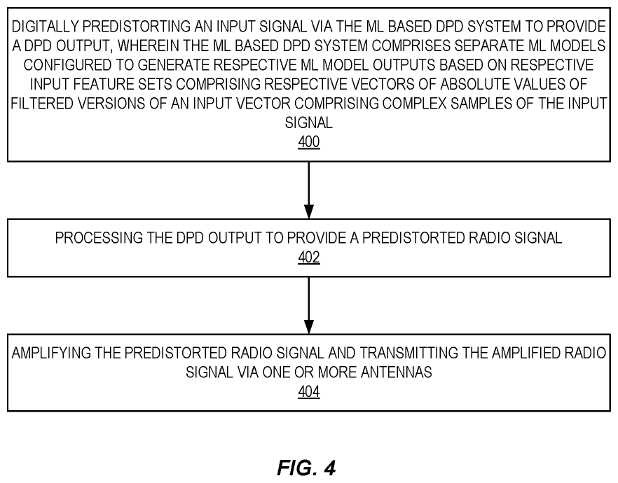

FIG. 4 is a flow chart that illustrates the operation of the radio node 100 of FIG. 1 in accordance with one embodiment of the present disclosure. As illustrated, the radio node 100 digitally predistorts the input signal via the ML-based DPD system 104 to provide the DPD output (step 400). The ML-based DPD system 104 includes separate ML models (e.g., ML models 312-1 to 312-M) configured to generate respective ML model outputs based on respective input feature sets that include respective vectors of absolute values of filtered versions of an input vector that includes complex samples of the input signal. The radio node 100 processes the DPD output to provide a predistorted radio signal (step 402). The radio node 100 amplifies the predistorted radio signal and transmits the amplified radio signal via one or more antennas (step 404).

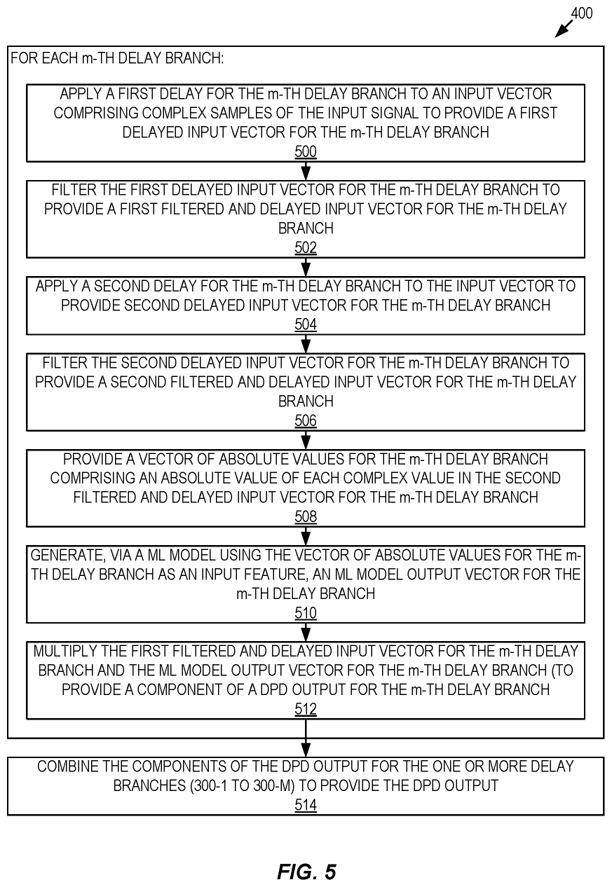

FIG. 5 is a flow chart that illustrates step 400 in more detail, in accordance with one embodiment of the present disclosure. Note that while the steps of FIG. 5 are shown in a particular order for ease of discussion, the steps may be performed in any desired order unless otherwise stated or required. This embodiment relates to the use and operation of the embodiment of the ML-based DPD system 104 of FIG. 3 and, as such, references to the elements of the embodiment of the ML-based DPS system 104 of FIG. 3 will sometimes be made in the following description of FIG. 5. As illustrated, for each delay branch 300-m, the ML-based DPD system 104 applies a first delay (e.g., Z^{-a} in the case of the first delay branch 300-1) to the input vector (X) to provide a first delayed input vector for the m-th delay branch 300-m (step 500) and filters the first delayed input vector to provide a first delayed and filtered input vector for the delay branch 300-m (step 502).

For each delay branch 300-m, the ML-based DPD system 104 also applies a second delay (e.g., Z^{-c} in the case of the first delay branch 300-1) to the input vector (X) to provide a second delayed input vector for the m-th delay branch 300-m (step 504) and filters the second delayed input vector to provide a second delayed and filtered input vector for the m-th delay branch 300-m (step 506). The ML-based DPD system 104 provides a vector including absolute values of the corresponding complex sample of the second delayed and filtered input vector for the m-th delay branch 300-m (step 508). The ML-based DPD system 104 generates, via the ML model 314-m for the m-th delay branch 300-m, a ML model output based on the vector of absolute values for the m-th delay branch 300-m (step 510). The ML-based DPD system 404 multiples the first delayed and filtered input vector for the m-th delay branch 300-m and the ML model output for the m-th delay branch 300-m to provide a component of the DPD output for the m-th delay branch 300-m (step 512).

Lastly, the ML-based DPD system 104 combines the M components of the DPD output from the M delay branches 300-1 to 300-M to provide the DPD output (step 514).

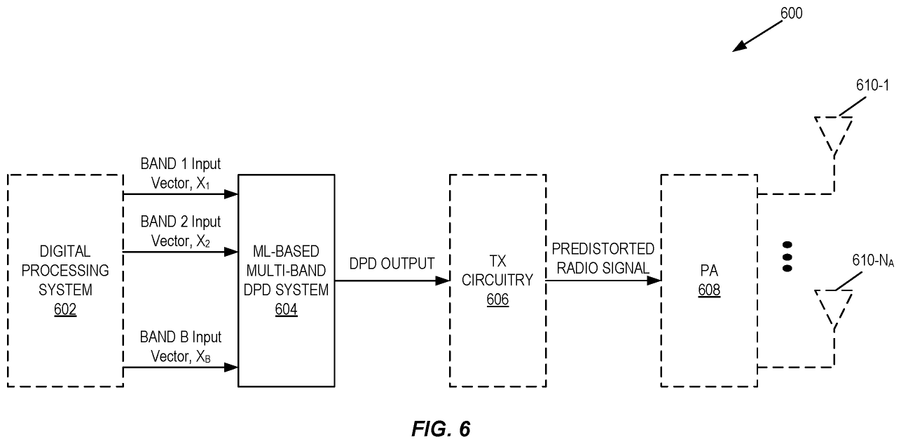

The extension of the proposed architecture to the multi-input or multi-band use case will now be described. For the multi-input use case, let X_{b}=[x_{b}(n) x_{b}(n−1) . . . . x_{b}(n−m+1) x_{b}(n−m)] denote complex input signal vector for the b-th band. FIG. 6 illustrates an example embodiment of a radio node 600 for the multi-input or multi-band case. Optional blocks are represented by dashed boxes/lines. As illustrated, the radio node 600 includes a digital processing system 102 (e.g., a DSP or the like) that generates the input vectors (X_{b}) for B frequency bands where b=1, . . . , B. The input vectors (X_{b}) include complex samples of corresponding input signals for the B frequency bands. The input vectors (X_{b}) for the B frequency bands are provided to a ML-based multi-band DPD system 604. The ML-based multi-band DPD system 604 may be implemented in hardware, software, or a combination thereof. In one example embodiment, the ML-based multi-band DPD system 604 is implemented by one or more ASICs. While the details of the ML-based multi-band DPD system 604 are described below, at a high-level, the ML-based multi-band DPD system 604 processes the input vectors (X_{b}) to provide a (multi-band) DPD output, which includes complex samples that represent a predistorted multi-band input signal in the digital domain. Transmit circuitry 606 processes the DPD output to provide a predistorted radio (e.g., radio frequency) signal, which is amplified by a PA 608 and transmitted via one or more antennas 610-1 through 610-N_{A}, where N_{A} is the number of antennas. As will be appreciated by those of ordinary skill in the art, the transmit circuitry 606 includes digital to analog conversion circuitry, upconversion circuitry (e.g., mixers), filters, and/or the like.

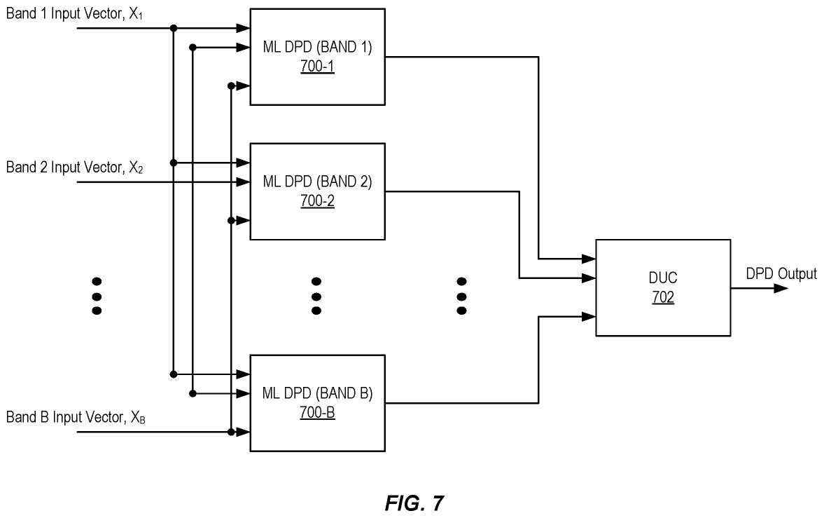

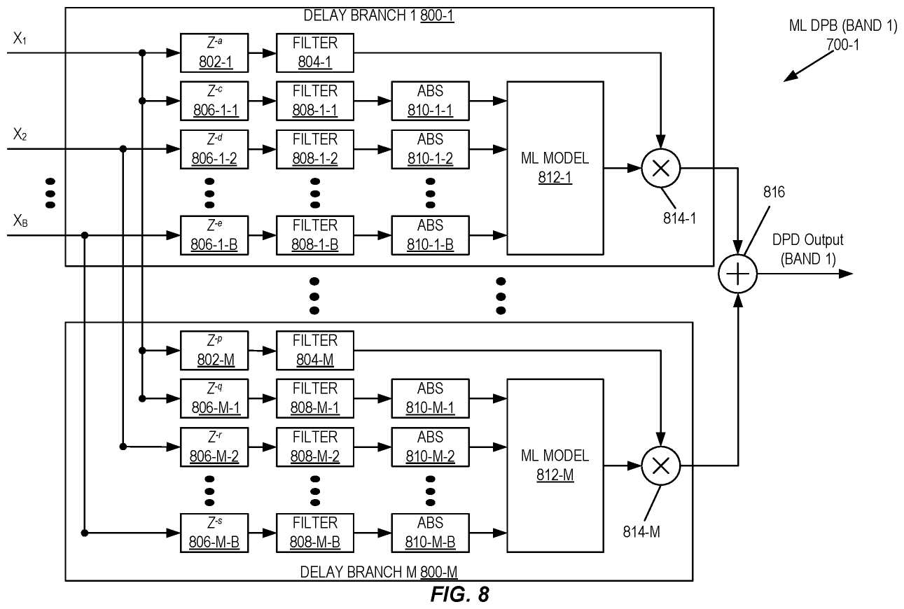

Details of an example embodiment of the ML-based multi-band DPD system 604 are shown in FIGS. 7 and 8. As illustrated in FIG. 7, the ML-based multi-band DPD system 604 includes separate ML-based DPD subsystems 700-1 to 700-B for the B frequency bands. DPD outputs of the ML-based DPD subsystems 700-1 to 700-B are combined via, in this example, a Digital Upconversion (DUC) function 702. The DUC function 702 upsamples and frequency translates the individual DPD outputs according to their desired carrier frequencies to thereby provide a multi-band DPD output.

FIG. 8 illustrates the ML-based DPD subsystem 700-1 for the first frequency band (i.e., BAND 1 or b=1) in accordance with one embodiment of the present disclosure. As illustrated, the ML-based DPD subsystem 700-1 includes M delay branches 800-1 to 800-M to provide a desired level of memory depth. Each delay branch 800-m (where m=1, . . . M) includes a first delay 802-m that applies a first delay to the input vector X₁ and a first filter 804-m that filters the output of the first filter 802-m to provide a first delayed and filtered input vector for the m-th delay branch 800-m. Each delay branch 800-m also includes, for each b-th frequency band, a delay 806-1-b and filter 802-1-b that provide a delayed and filtered input vector for the b-th frequency band. For each b-th frequency band, an absolute value function 810-1-b provides a vector of absolute values of corresponding complex samples of the delayed and filtered input vector for the b-th frequency band for the delay branch 800-m. The B vectors output by the absolute value functions 810-1-1 to 810-1-B of the delay branch 800-m are provided as input features to a ML model 812-m of the delay branch 800-m and, based thereon, the ML model 812-m provides a ML model output for the delay branch 800-m. A multiplier 814-m multiples the first delayed and filtered input vector for the delay branch 800-m and the ML model output for the delay branch 800-m to provide a component of the DPD output for the delay branch 800-m. A combiner 816 combines the M components of the DPD output from the M delay branches 800-1 to 800-M to provide a DPD output for the frequency band, which in this example is the first frequency band (BAND 1). Note that, in the illustrated example embodiments, the combiner 816 is an adder. However, other combining mechanisms can be used. For example, in another embodiment, the combiner 816 is another ML model that combines the M components of the DPD output from the M delay branches 800-1 to 800-M to provide a DPD output for the frequency band, which in this example is the first frequency band (BAND 1). This ML model will take care of the interaction among different delay branches and is, in one example embodiment, trained together with the other ML models 812-1 to 812-M across all of the ML DPD subsystems 700-1 to 700-B to provide the desired (multi-band) DPD output for a given set of input vectors for the B frequency bands.

The ML-based DPD subsystems 700-2 through 700-M are the same as that of FIG. 8 but where, for each delay branch 800-m, the first delay 802-m and the first filter 804-m process the input vector X_{b} for the respective frequency band (i.e., X₂ for the ML-based DPD subsystem 700-2, X₃ for the ML-based DPD subsystem 700-3, etc.).

Using the architecture of FIG. 8, different amounts of delay, filter coefficients, and ML models can be used for different frequency bands. Further, as can be seen, the ML models 812-m consider filtered absolute values (also referred to as “amplitude values”) from different bands. As a result, multi-dimensional LUT based DPD is not needed. Since the same architecture can be reused for different scenarios, the proposed architecture can support single and multiband DPD with the same DPD module. In addition, the proposed DPD architecture can use existing DPD adaptation for ML model update, which leads to faster time to market and reduces implementation and verification costs compared to other machine learning based DPD solutions.

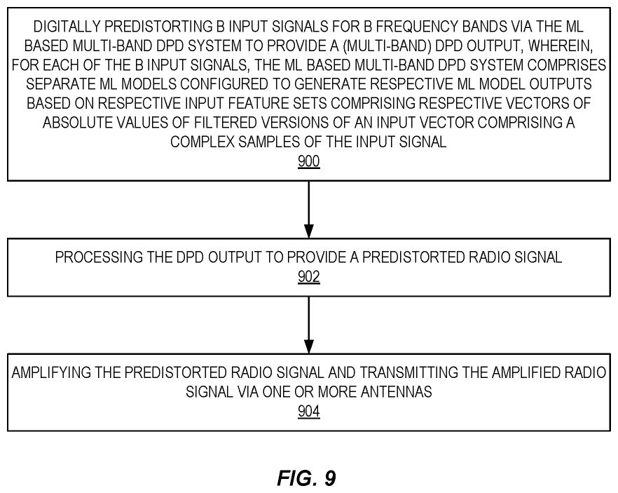

FIG. 9 is a flow chart that illustrates the operation of the radio node 600 of FIG. 6 in accordance with one embodiment of the present disclosure. As illustrated, the radio node 600 digitally predistorts the input signals for the B frequency bands via the ML-based multi-band DPD system 604 to provide the (multi-band) DPD output (step 500). For each frequency band, the ML-based multi-band DPD system 604 includes separate ML models (e.g., ML models 812-1 to 812-M) configured to generate respective ML model outputs based on respective input feature sets that include vectors of absolute values of filtered versions of input vectors that includes complex samples of the input signals for the B frequency bands. The radio node 600 processes the DPD output to provide a predistorted (multi-band) radio signal (step 502). The radio node 600 amplifies the predistorted radio signal and transmits the amplified radio signal via one or more antennas (step 504).

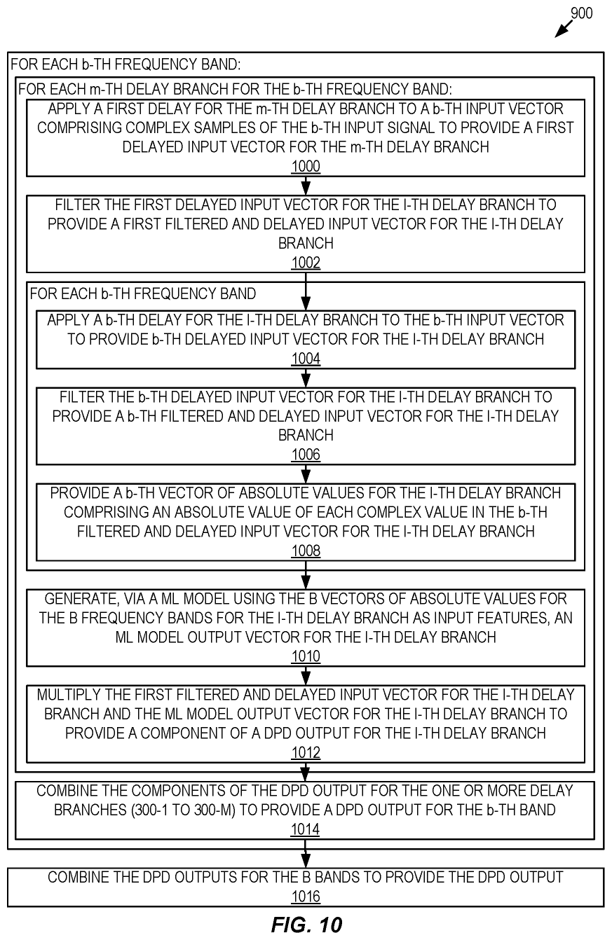

FIG. 10 is a flow chart that illustrates step 900 in more detail, in accordance with one embodiment of the present disclosure. Note that while the steps of FIG. 10 are shown in a particular order for ease of discussion, the steps may be performed in any desired order unless otherwise stated or required. This embodiment relates to the use and operation of the embodiment of the ML-based multi-band DPD system 604 of FIG. 8 and, as such, references to the elements of the embodiment of the ML-based multi-band DPD system 604 of FIG. 8 will sometimes be made in the following description of FIG. 10.

As illustrated, the ML-based multi-band DPD system 604 performs the following actions:
for each b-th frequency band, in order to generate the DPD output for the b-th frequency band:
   for each delay branch 800-m of the ML based DPD subsystem 700-b for the b-th frequency band:
      apply a first delay to the input vector X_{b} for the b-th frequency band to provide a first delayed input vector for the m-th delay branch 800-m (step 1000);
      filter the first delayed input vector to provide a first delayed and filtered input vector for the delay branch 800-m (step 1002);
      for each b-th frequency band:
         apply a b-th delay for the delay branch 800-m to the input vector X_{b} to provide a b-th delayed input vector for the m-th delay branch 800-m (step 1004);
         filter the b-th delayed input vector for the m-th delay branch 800-m to provide a b-th delayed and filtered input vector for the m-th delay branch 800-m (step 1006);
         provide a vector including absolute values of the corresponding complex sample of the b-th delayed and filtered input vector for the m-th delay branch 800-m (step 1008);
      generate, via the ML model 814-m for the m-th delay branch 800-m, a ML model output based on the vectors of absolute values for the B frequency bands provided for the m-th delay branch 800-m (step 1010);
      multiply the first delayed and filtered input vector for the m-th delay branch 800-m and the ML model output for the m-th delay branch 800-m to provide a component of the DPD output (step 1012);
   combine the M components of the DPD output from the M delay branches 800-1 to 800-M to provide the DPD output for the b-th frequency band (step 1014); and
   combine the DPD outputs for the B frequency bands to provide the (multi-band) DPD output (step 1016).

Any appropriate steps, methods, features, functions, or benefits disclosed herein may be performed through one or more functional units or modules of one or more virtual apparatuses. Each virtual apparatus may comprise a number of these functional units. These functional units may be implemented via processing circuitry, which may include one or more microprocessor or microcontrollers, as well as other digital hardware, which may include Digital Signal Processors (DSPs), special-purpose digital logic, and the like. The processing circuitry may be configured to execute program code stored in memory, which may include one or several types of memory such as Read Only Memory (ROM), Random Access Memory (RAM), cache memory, flash memory devices, optical storage devices, etc. Program code stored in memory includes program instructions for executing one or more telecommunications and/or data communications protocols as well as instructions for carrying out one or more of the techniques described herein. In some implementations, the processing circuitry may be used to cause the respective functional unit to perform corresponding functions according one or more embodiments of the present disclosure.

While processes in the figures may show a particular order of operations performed by certain embodiments of the present disclosure, it should be understood that such order is exemplary (e.g., alternative embodiments may perform the operations in a different order, combine certain operations, overlap certain operations, etc.).

Those skilled in the art will recognize improvements and modifications to the embodiments of the present disclosure. All such improvements and modifications are considered within the scope of the concepts disclosed herein.

1. A radio node for a wireless network, comprising:
a machine learning, ML, based digital predistortion, DPD, system configured to digitally predistort one or more input signals to provide a DPD output, wherein the ML based DPD system comprises, for each input signal of the one or more input signals, separate ML models configured to generate respective ML model outputs based on respective input feature sets comprising respective vectors of absolute values of filtered versions of an input vector comprising a plurality of complex samples of the input signal;
transmit circuitry configured to process the DPD output to provide a predistorted radio signal; and
power amplifier circuitry configured to amplify the predistorted radio signal.

2. The radio node of claim 1 wherein the one or more input signals consist of an input signal, and the ML based DPD system comprises:
for each m-th delay branch of two or more delay branches of the ML based DPD system:
a first delay configured to apply a first delay for the m-th delay branch to an input vector comprising a plurality of complex samples of an input signal to provide a first delayed input vector for the m-th delay branch;
a first filter configured to filter the first delayed input vector for the m-th delay branch to provide a first filtered and delayed input vector for the m-th delay branch; and
a second delay configured to apply a second delay for the m-th delay branch to the input vector to provide a second delayed input vector for the m-th delay branch;
a second filter for the m-th delay branch configured to filter the second delayed input vector for the m-th delay branch to provide a second filtered and delayed input vector for the m-th delay branch;
an absolute value function configured to provide a vector of absolute values for the m-th delay branch comprising an absolute value of each complex value in the second filtered and delayed input vector for the m-th delay branch;
an ML model configured to receive the vector of absolute values for the m-th delay branch as an input feature and output an ML model output vector for the m-th delay branch; and
a multiplication function for the m-th delay branch configured to multiply the first filtered and delayed input vector for the m-th delay branch and the ML model output vector for the m-th delay branch to provide a component of a DPD output for the m-th delay branch; and
a combining function configured to combine the components of the DPD output for the two or more delay branches to provide the DPD output.

3. The radio node claim 2 wherein the combining function is an addition function.

4. The radio node claim 2 wherein the combining function is an ML model.

5. The radio node of claim 2 wherein, for each m-th delay branch, the first delay and the second delay are such that the first filtered and delayed input vector for the m-th delay branch and the ML model output vector for the m-th delay branch are time-aligned at the multiplication function for the m-th delay branch.

6. (canceled)

7. The radio node of claim 2 wherein the input signal is a single band input signal.

8. The radio node of claim 2 wherein the input signal is a multi-band input signal.

9. The radio node of claim 1 wherein the one or more input signals comprise two or more input signals for two or more frequency bands, respectively.

10. The radio node of claim 9 wherein the ML based DPD system comprises two or more ML based DPD subsystems for the two or more frequency bands, respectively.

11. The radio node of claim 10 wherein, for b=1, . . . , B where B is the number of frequency bands in the two or more frequency bands, each b-th ML based DPD subsystem from among the two or more ML based DPD subsystems comprises:
for each m-th delay branch of one or more delay branches M) of the b-th ML based DPD subsystem:
a first delay configured to apply a first delay for the m-th delay branch to a b-th input vector comprising a plurality of complex samples of the b-th input signal to provide a first delayed input vector for the m-th delay branch;
a first filter configured to filter the first delayed input vector for the m-th delay branch to provide a first filtered and delayed input vector for the m-th delay branch;
for each b-th frequency band:
a b-th delay for the m-th delay branch configured to apply a b-th delay for the m-th delay branch to the b-th input vector to provide a b-th delayed input vector for the m-th delay branch;
a b-th filter for the m-th delay branch configured to filter the b-th delayed input vector for the m-th delay branch to provide a b-th filtered and delayed input vector for the m-th delay branch; and
an absolute value function configured to provide a b-th vector of absolute values for the m-th delay branch comprising an absolute value of each complex value in the b-th filtered and delayed input vector for the m-th delay branch;
an ML model configured to receive the B vectors of absolute values for the m-th delay branch as input features and output an ML model output vector for the m-th delay branch; and
a multiplication function for the m-th delay branch configured to multiply the first filtered and delayed input vector for the m-th delay branch and the ML model output vector for the m-th delay branch to provide a component of a DPD output for the m-th delay branch; and
a combining function configured to combine the components of the DPD output for the one or more delay branches to provide a DPD output for the b-th frequency band.

12. The radio node claim 11 wherein the combining function is an addition function.

13. The radio node claim 11 wherein the combining function is an ML model.

14. The radio node of claim 11 wherein the ML based DPD system further comprises combining circuitry configured to combine the DPD outputs for the B frequency bands to provide the DPD output of the ML based digital DPD system.

15. A method performed by a radio node for a wireless network, comprising:
digitally predistorting one or more input signals via a machine learning, ML, based digital predistortion, DPD, system to provide a DPD output, wherein the ML based DPD system comprises, for each input signal of the one or more input signals, separate ML models configured to generate respective ML model outputs based on respective input feature sets comprising respective vectors of absolute values of filtered versions of an input vector comprising a plurality of complex samples of the input signal;
processing the DPD output to provide a predistorted radio signal; and
amplifying the predistorted radio signal.

16. The method of claim 15 wherein the one or more input signals consist of an input signal, and digitally predistorting the input signal via the ML based DPD system comprises:
for each m-th delay branch of two or more delay branches of the ML based DPD system: applying a first delay for the m-th delay branch to an input vector comprising a plurality of complex samples of an input signal to provide a first delayed input vector for the m-th delay branch;
filtering the first delayed input vector for the m-th delay branch to provide a first filtered and delayed input vector for the m-th delay branch;
applying a second delay for the m-th delay branch to the input vector to provide a second delayed input vector for the m-th delay branch;
filtering the second delayed input vector for the m-th delay branch to provide a second filtered and delayed input vector for the m-th delay branch;
providing a vector of absolute values for the m-th delay branch comprising an absolute value of each complex value in the second filtered and delayed input vector for the m-th delay branch;
generating via an ML model using the vector of absolute values for the m-th delay branch as an input feature, an ML model output vector for the m-th delay branch; and
multiplying the first filtered and delayed input vector for the m-th delay branch and the ML model output vector for the m-th delay branch to provide a component of a DPD output for the m-th delay branch; and
combining the components of the DPD output for the two or more delay branches to provide the DPD output.

17. (canceled)

18. The method of claim 16 wherein the input signal is a single band input signal.

19. The method of claim 16 wherein the input signal is a multi-band input signal.

20. The method of claim 15 wherein the one or more input signals comprise two or more input signals for two or more frequency bands, respectively.

21. The method of claim 20 wherein, for b=1, . . . , B where B is the number of frequency bands in the two or more frequency bands, and digitally predistorting the input signal via the ML based DPD system comprises, for each b-th frequency band from among the two or more frequency bands:
for each m-th delay branch of one or more delay branches M) of the ML based DPD system for the b-th frequency band:
applying a first delay for the m-th delay branch to a b-th input vector comprising a plurality of complex samples of the b-th input signal to provide a first delayed input vector for the m-th delay branch;
filtering the first delayed input vector for the m-th delay branch to provide a first filtered and delayed input vector for the m-th delay branch;
for each b-th frequency band:
applying a b-th delay for the m-th delay branch to the b-th input vector to provide a b-th delayed input vector for the m-th delay branch;
filtering the b-th delayed input vector for the m-th delay branch to provide a b-th filtered and delayed input vector for the m-th delay branch; and
providing a b-th vector of absolute values for the m-th delay branch comprising an absolute value of each complex value in the b-th filtered and delayed input vector for the m-th delay branch;
generating via an ML model using the B vectors of absolute values for the m-th delay branch as input features, an ML model output vector for the m-th delay branch; and
multiplying the first filtered and delayed input vector for the m-th delay branch and the ML model output vector for the m-th delay branch to provide a component of a DPD output for the m-th delay branch; and
combining the components of the DPD output for the one or more delay branches to provide a DPD output for the b-th frequency band.

22. The method of claim 21 further comprising combining the DPD outputs for the B frequency bands to provide the DPD output of the ML based digital DPD system.
